(19) United States
(12) Patent Application Publication
(10) Pub. No.: US 2025/0385137 A1
(43) Pub. Date: Dec. 18, 2025

(54) EXPANSION METHOD AND EXPANSION APPARATUS

(71) Applicant: DISCO CORPORATION, Tokyo (JP)

(72) Inventors: Shinya ARUGA, Tokyo (JP); Yusuke FUJII, Tokyo (JP)

(21) Appl. No.: 19/206,463

(22) Filed: May 13, 2025

(30) Foreign Application Priority Data
Jun. 13, 2024 (JP) 2024-095572

(51) Int. Cl. H01L 21/78; H01L 21/68

(52) U.S. Cl. CPC H01L 21/78; H01L 21/68; H01L 2221/68318; H01L 2221/68327

(57) ABSTRACT

Disclosed is an expansion method for expanding an expandable sheet of a workpiece unit including a plate-shaped workpiece, a first ring frame, and the expandable sheet attached to the workpiece and the first ring frame. A central area of the expandable sheet is pressed in directions inclined radially outward with respect to a direction perpendicular to an opening of the first ring frame, distances between respective chips formed as a result of division of the workpiece are increased, and the expanded expandable sheet is fixed to a second ring frame.

### BACKGROUND OF THE INVENTION

### Field of the Invention

The present invention relates to an expansion method and an expansion apparatus for expanding an expandable sheet of a workpiece unit including a plate-shaped workpiece in which division initiating points or division grooves have been formed, a ring frame disposed to surround the workpiece, and the expandable sheet attached to the workpiece and the ring frame.

### Description of the Related Art

In a process of manufacturing device chips, there is used a disk-shaped wafer formed with devices such as integrated circuits (ICs) and large scale integration (LSI) circuits in respective areas partitioned by a plurality of projected dicing lines (streets) that intersect. This wafer is divided along the projected dicing lines, so that a plurality of device chips each having a device formed thereon are obtained. The device chips are mounted on various types of electronic equipment such as mobile phones and personal computers. In division of a plate-shaped workpiece such as a semiconductor wafer, for example, a cutting apparatus having an annular cutting blade is used (refer to Japanese Patent Laid-open No. 2019-192846). Alternatively, in division of a workpiece, a laser processing apparatus that irradiates the workpiece with a laser beam is used.

When a workpiece is to be carried in a cutting apparatus or the like, a workpiece unit is formed by integrating the workpiece, a ring frame having an opening of a size large enough to accommodate the workpiece, and an adhesive tape attached to the ring frame in a manner closing the opening of the ring frame. In this workpiece unit, the workpiece is attached to the adhesive tape at a position inside the opening of the ring frame. After the workpiece is divided by the cutting apparatus or the like, individual chips formed as a result are kept being supported by the ring frame through the adhesive tape. Thereafter, the individual chips are picked up from the adhesive tape and mounted to predetermined targets. In this respect, for the purpose of facilitating the pick-up of chips from the adhesive tape, after the division of the workpiece, the adhesive tape is expanded toward its outer periphery inside the opening of the ring frame, so that spaces between the individual chips are enlarged. The adhesive tape is thus also called an expandable sheet.

There is known a technique of, after expanding the expandable sheet to enlarge the spaces between the chips, heating an area of the expandable sheet exposed between the workpiece and the ring frame to cause shrinkage of the area, thereby maintaining the enlarged spaces between the chips (refer to Japanese Patent Laid-open No. 2021-19138). This technique is called heat shrinking in some cases.

In addition, there is known a technique of preparing an inner ring and an outer ring having an inner diameter slightly larger than an outer diameter of the inner ring and then sandwiching and fixing the expanded expandable sheet between the inner ring and the outer ring (refer to Japanese Patent Laid-open No. 2020-191328). For example, after the expandable sheet is expanded, the expandable sheet is sandwiched between the two rings at a position inside the opening of the ring frame. More specifically, the inner ring is disposed on a lower surface of the expandable sheet, and the outer ring set above the expandable sheet is moved downward in such a manner as to accommodate the inner ring therein, so that the expandable sheet is sandwiched between the two rings internally and externally. The enlarged spaces between the chips are maintained in this manner. In this case, the expandable sheet is cut at a position outside the area thereof sandwiched between the two rings, so that the workpiece (chips) is separated from the ring frame.

### SUMMARY OF THE INVENTION

In the case where the enlarged spaces between the chips are maintained by heat shrinking, a configuration for heating a predetermined area of the expandable sheet is required to be mounted in an expansion apparatus that expands the expandable sheet, and this increases cost of the expansion apparatus. Moreover, in the case where heat shrinking is performed, it takes time to perform a step of sufficiently heating the expandable sheet, leading to a reduction in manufacturing efficiency of chips. Furthermore, in the case where the expandable sheet is sandwiched between the inner ring and the outer ring, the two rings need to be thicker than the ring frame in order to sandwich the expandable sheet between the two rings with sufficient fixing force. Thus, the integrated object including the expandable sheet sandwiched between the two rings and the respective chips has an increased thickness. Hence, when a plurality of such integrated objects are accommodated in a cassette and transported, significant limitation is imposed on the number of integrated objects that can be accommodated in the cassette. That is, such integrated objects are inferior in transportability, causing a reduction in manufacturing efficiency of chips.

Accordingly, it is an object of the present invention to provide an expandable sheet expansion method and apparatus capable of expanding an expandable sheet so as to efficiently manufacture chips.

In accordance with an aspect of the present invention, there is provided an expansion method for expanding an expandable sheet of a workpiece unit including a plate-shaped workpiece in which division initiating points or division grooves are formed, a first ring frame having an opening and disposed to surround the workpiece, and the expandable sheet attached to the workpiece and the first ring frame. The expansion method includes disposing the first ring frame of the workpiece unit on a first support unit, disposing a second ring frame having an opening, on a second support unit overlapping the first support unit, and radially expanding, after disposing the first ring frame and the second ring frame, the expandable sheet by pressing the expandable sheet at a position inside the opening of the first ring frame. In the expanding, a central area of the expandable sheet which central area is surrounded by an area attached to the first ring frame is pressed in directions inclined radially outward with respect to a direction perpendicular to the opening of the first ring frame. In the expanding, distances between respective chips formed as a result of division of the workpiece with use of the division initiating points or the division grooves as boundaries are increased. In the expanding, the expanded expandable sheet is fixed to the second ring frame disposed on the second support unit.

Preferably, a planar shape of the first ring frame coincides with a planar shape of the second ring frame, when the first ring frame and the second ring frame are disposed, the opening of the first ring frame overlaps the opening of the second ring frame, and part of a portion of the expandable sheet yet to be expanded which portion is exposed between the first ring frame and the workpiece enters an area sandwiched between the first ring frame and the second ring frame when the expanding is performed.

More preferably, the expansion method further includes cutting, after the expanding, the expandable sheet fixed to the second ring frame along the opening of the second ring frame.

In accordance with another aspect of the present invention, there is provided an expansion apparatus for expanding an expandable sheet of a workpiece unit including a plate-shaped workpiece in which division initiating points or division grooves are formed, a first ring frame having an opening and disposed to surround the workpiece, and the expandable sheet attached to the workpiece and the first ring frame. The expansion apparatus includes a first support unit that supports the first ring frame of the workpiece unit, a second support unit that supports a second ring frame having an opening, the second support unit overlapping the first support unit, and a sheet pressing expansion unit capable of pressing a central area of the expandable sheet of the workpiece unit having the first ring frame supported by the first support unit which central area is surrounded by an area attached to the first ring frame, in pressing directions inclined radially outward with respect to a direction perpendicular to the opening of the first ring frame. The sheet pressing expansion unit is capable of expanding the expandable sheet to increase distances between respective chips formed as a result of division of the workpiece with use of the division initiating points or the division grooves as boundaries, and also capable of fixing the expanded expandable sheet to the second ring frame disposed on the second support unit.

Preferably, the sheet pressing expansion unit includes a movement support section, a drive section that moves the movement support section along the direction perpendicular to the opening of the first ring frame supported by the first support unit, and pressing sections that are supported by the movement support section through guide portions and press the expandable sheet, and the guide portions guide the respective pressing sections in such a manner that the pressing sections move in the respective pressing directions.

More preferably, a planar shape of the first ring frame supported by the first support unit coincides with a planar shape of the second ring frame supported by the second support unit.

Further preferably, the expansion apparatus further includes a cutter for cutting the expandable sheet fixed to the second ring frame along the opening of the second ring frame.

With the expansion method and the expansion apparatus according to one aspect of the present invention, when the expandable sheet attached to the first ring frame is pressed and radially expanded, the central area of the expandable sheet is pressed in the directions (pressing directions) inclined radially outward with respect to the direction perpendicular to the opening of the first ring frame. The expandable sheet thus expanded is fixed to the second ring frame. Here, the expandable sheet is not merely pressed in the direction perpendicular to the opening of the first ring frame but pressed in the directions inclined radially outward and expanded. Therefore, a large flat area can be formed in the expandable sheet around the workpiece (divided chips). In this case, since the expandable sheet is attached to the second ring frame in this relatively large flat area, the expandable sheet is attached to the second ring frame by sufficient fixing force.

Thus, with the expansion method and the expansion apparatus according to one aspect of the present invention, the expanded expandable sheet can be fixed by sufficient fixing force without the use of an inner ring and an outer ring having a large thickness, so that chips can efficiently be transported using a cassette. In addition, heat shrinking is unnecessary, and the time and configurations required for heat shrinking can be omitted. Therefore, the time and cost required for relevant steps can be reduced, so that chips can be manufactured with high efficiency.

Thus, according to one aspect of the present invention, there are provided an expandable sheet expansion method and apparatus capable of expanding an expandable sheet so as to efficiently manufacture chips.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view schematically illustrating a front surface side of a workpiece;

FIG. 1B is a perspective view schematically illustrating a back surface side of the workpiece;

FIG. 2A is a perspective view schematically illustrating how division initiating points are formed in the workpiece;

FIG. 2B is a cross-sectional view schematically illustrating how the division initiating points are formed in the workpiece;

FIG. 3 is a perspective view schematically illustrating a workpiece unit including the workpiece in which the division initiating points have been formed;

FIG. 4 is a perspective view schematically illustrating a support unit of an expansion apparatus;

FIG. 5A is a cross-sectional view schematically illustrating the workpiece unit disposed on a first support unit and a second ring frame disposed on a second support unit;

FIG. 5B is a cross-sectional view schematically illustrating how a sheet pressing expansion unit is moved downward;

FIG. 6A is a cross-sectional view schematically illustrating how an expandable sheet is pressed downward;

FIG. 6B is a cross-sectional view schematically illustrating how the expandable sheet is pressed in directions inclined outward and is fixed to the second ring frame;

FIG. 7A is a cross-sectional view schematically illustrating how the expandable sheet is cut;

FIG. 7B is a cross-sectional view schematically illustrating an integrated object including the second ring frame, the workpiece, and the expandable sheet;

FIG. 8 is a cross-sectional view schematically illustrating a configuration example of the sheet pressing expansion unit;

FIG. 9 is a cross-sectional view schematically illustrating the sheet pressing expansion unit in which a pressing section has moved in directions inclined outward with respect to the downward direction;

FIG. 10 is a flowchart illustrating a flow of steps in an expansion method for expanding the expandable sheet;

FIG. 11A is a cross-sectional view schematically illustrating an expansion apparatus according to a modification example; and

FIG. 11B is a cross-sectional view schematically illustrating how the expandable sheet is expanded in the expansion apparatus according to the modification example.

### DETAILED DESCRIPTION OF THE PREFERRED EMBODIMENT

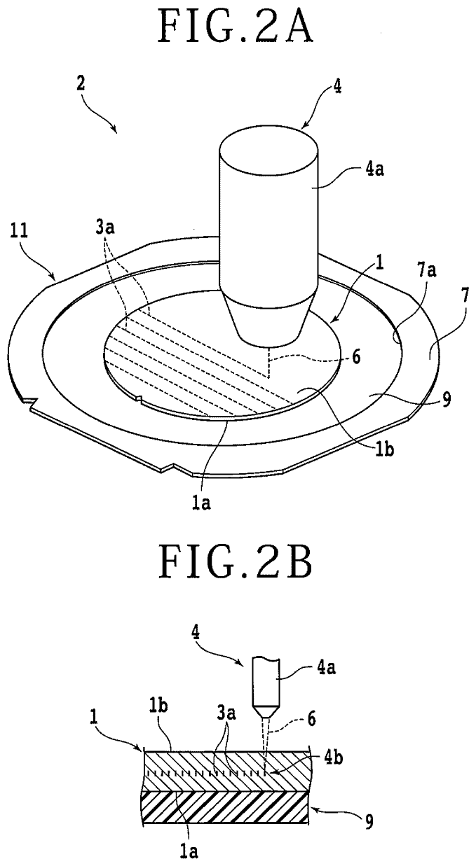

An embodiment according to one aspect of the present invention is described with reference to the accompanying drawings. First, description is made of a workpiece unit including an expandable sheet to be expanded by an expansion method and an expansion apparatus according to the present embodiment. FIG. 2A is a perspective view schematically illustrating a workpiece unit 11. As illustrated in FIG. 2A, the workpiece unit 11 includes a plate-shaped workpiece 1, a first ring frame 7 disposed to surround the workpiece 1, and an expandable sheet 9 fixed to the workpiece 1 and the first ring frame 7. The workpiece 1 to be processed is disposed inside an opening 7a of the first ring frame 7. The expandable sheet 9 is then fixed to the workpiece 1 and the first ring frame 7 in a manner closing the opening 7a of the first ring frame 7. The workpiece 1, the expandable sheet 9, and the first ring frame 7 are thus integrated to form the workpiece unit 11. At this time, for example, the expandable sheet 9 is disposed on a front surface 1a side of the workpiece 1, and a back surface 1b side of the workpiece 1 is exposed externally.

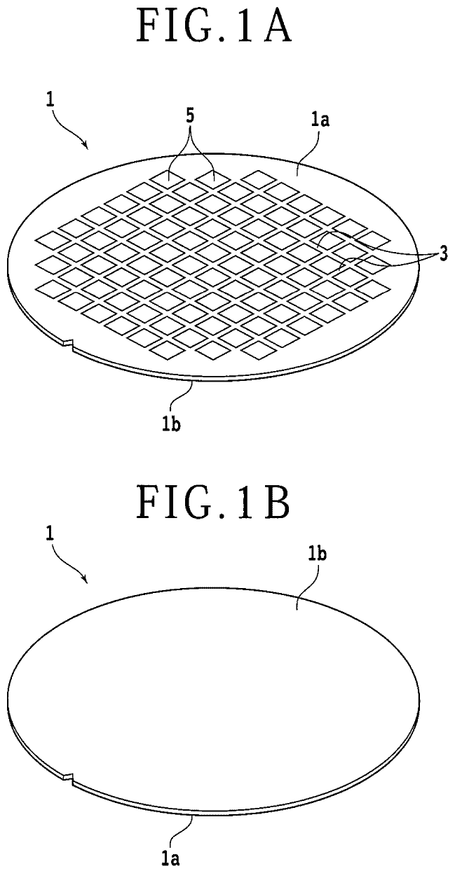

Described next are the respective components included in the workpiece unit 11. FIG. 1A is a perspective view schematically illustrating the front surface la side of the plate-shaped workpiece 1, and FIG. 1B is a perspective view schematically illustrating the back surface 1b side of the workpiece 1.

The plate-shaped workpiece 1 is, for example, made of silicon (Si), silicon carbide (Sic), gallium nitride (GaN), or any of other semiconductor materials (e.g., GaAs and InP). Alternatively, the workpiece 1 is a plate-shaped substrate (wafer) made of such a material as a complex oxide such as lithium tantalate (LT) or lithium niobate (LN). It is to be noted that there is no limitation in the material, structure, size, and the like of the workpiece 1. For example, the workpiece 1 may be a substrate made of sapphire, glass (e.g., quartz glass and borosilicate glass), or the like. The workpiece 1 is not necessarily in a disk shape and may be in a rectangular plate shape. A plurality of projected dicing lines 3 that intersect are set on the front surface la of the workpiece 1, and devices 5 such as ICs and LSI circuits are formed in respective areas partitioned by the projected dicing lines 3. By dividing the workpiece 1 along the projected dicing lines 3, individual device chips (chips or individual pieces) can be formed. It is to be noted that there is no limitation in the kind, quantity, shape, structure, size, layout, and the like of the devices 5 and that the workpiece 1 does not necessarily have the devices 5 formed thereon.

To divide the workpiece 1, for example, a laser processing apparatus that can focus, inside the workpiece 1, a laser beam of a wavelength to which the workpiece 1 is permeable (a wavelength that can be transmitted through the workpiece 1) is used. FIG. 2A is a perspective view schematically illustrating the workpiece 1 being laser-processed by a laser processing apparatus 2. As illustrated in FIG. 2A, the workpiece 1 is carried in the laser processing apparatus 2 in a state of being included in the workpiece unit 11.

The first ring frame 7 is, for example, made of a metallic material or the like and is a ring frame having the opening 7a of a diameter larger than a diameter of the workpiece 1. When the workpiece unit 11 is to be formed, the workpiece 1 is positioned inside the opening 7a of the first ring frame 7 and accommodated in the opening 7a. The expandable sheet 9 has a diameter larger than the diameter of the opening 7a of the first ring frame 7. The expandable sheet 9 is, for example, a tape including a base material layer and an adhesive layer formed on the base material layer, the tape being called a dicing tape. In the case where the expandable sheet 9 is a dicing tape, the expandable sheet 9 is attached to the first ring frame 7 and the workpiece 1 by adhesive force of the adhesive layer. Alternatively, the expandable sheet 9 may be, for example, a resin-based sheet such as a polyolefin-based sheet or a polyester-based sheet which does not have an adhesive layer. In this case, the expandable sheet 9 is thermocompression-bonded to the workpiece 1 and the first ring frame 7. In the case where the expandable sheet 9 is thermocompression-bonded to the workpiece 1 and the first ring frame 7, the expandable sheet 9 is pressed against the workpiece 1 and the first ring frame 7 while it is heated to a temperature close to its melting point or softening point. The expandable sheet 9 can thus be fixed to the workpiece 1 and the first ring frame 7 without the use of the adhesive force of the adhesive layer.

In the laser processing apparatus 2, a laser beam 6 of a wavelength that can be transmitted through the workpiece 1 is focused inside the workpiece 1, and modified layers serving as division initiating points along the projected dicing lines 3 are formed inside the workpiece 1. Now, description is made of the laser processing apparatus 2 that forms the modified layers serving as the division initiating points inside the plate-shaped workpiece 1. The laser processing apparatus 2 includes a holding table (chuck table) (not illustrated) for holding the workpiece 1 through the expandable sheet 9 and a laser processing unit 4 that irradiates the workpiece 1 held on the holding table with the laser beam 6.

The laser processing unit 4 has a processing head 4a for focusing, inside the workpiece 1, the laser beam 6 of the wavelength to which the workpiece 1 is permeable. The laser processing unit 4 includes a laser oscillator that has a medium of Nd:YAG or the like and that oscillates a pulsed laser beam having a wavelength of 1064 nm, for example. FIG. 2B is a cross-sectional view schematically illustrating the workpiece 1 being laser-processed. The workpiece 1 and the laser beam 6 are moved relative to each other along each of the projected dicing lines 3 while the laser beam 6 is focused on a focusing point 4b positioned at a predetermined depth inside the workpiece 1. The workpiece 1 is thus irradiated with the laser beam 6 along each of the projected dicing lines 3, so that modified layers 3a are formed along the projected dicing lines 3 inside the workpiece 1.

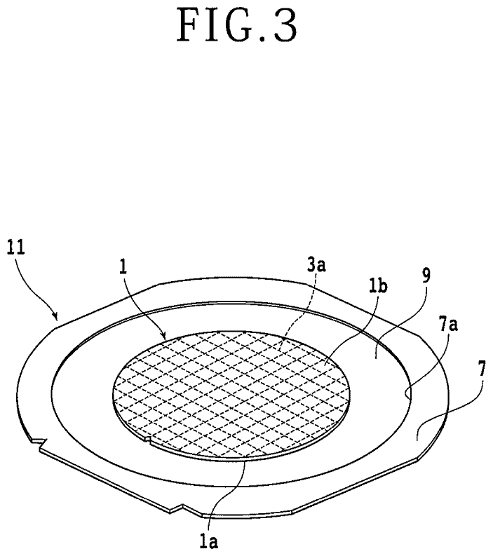

FIG. 3 is a perspective view schematically illustrating the workpiece unit 11 including the workpiece 1 in which the division initiating points (modified layers 3a) have been formed. FIG. 3 schematically illustrates the workpiece 1 with the modified layers 3a formed therein along the projected dicing lines 3, and the modified layers 3a formed inside the workpiece 1 are indicated by broken lines. When the modified layers 3a are formed, cracks may also be formed extending from the modified layers 3a toward the front surface la and the back surface 1b of the workpiece 1. It is also possible to apply external force to the workpiece 1 with the modified layers 3a formed therein, thereby causing cracks to extend from the modified layers 3a. The external force is applied to the workpiece 1 by, for example, pressing of the workpiece 1 with use of an unillustrated pressing member. Alternatively, external force is applied to the workpiece 1 by expansion of the expandable sheet 9 outward in radial directions inside the opening 7a of the first ring frame 7. After the modified layers 3a and the cracks extending from the modified layers 3a have been formed in the workpiece 1, the workpiece 1 is divided along the projected dicing lines 3. That is, the modified layers 3a act as the division initiating points at the time of division of the workpiece 1.

It is to be noted that the laser processing unit 4 may irradiate the workpiece 1 with a laser beam 6 of a wavelength absorbable by the workpiece 1, in place of the laser beam 6 of the wavelength that can be transmitted through the workpiece 1. In this case, the workpiece 1 is ablated by the irradiation with the laser beam 6, and division grooves are formed in place of the modified layers 3a. Further alternatively, a cutting apparatus having an annular cutting blade may be used to divide the workpiece 1, and division grooves may be formed in the workpiece 1 by the cutting blade.

The individual chips (device chips) formed as a result of the division of the workpiece 1 are kept being supported by the expandable sheet 9. The expandable sheet 9 is then expanded to enlarge spaces between the chips, so that it becomes easy to pick up the chips. However, after the expansion of the expandable sheet 9, the expandable sheet 9 needs to be maintained in its expanded state. The expansion method and the expansion apparatus for expanding the expandable sheet 9 according to the present embodiment described below make it possible to efficiently maintain the expanded state of the expanded expandable sheet 9. The expanded expandable sheet 9 is fixed to a ring frame (second ring frame 13) different from the first ring frame 7 included in the workpiece unit 11. The expandable sheet 9 is thus maintained in its expanded state. That is, the state in which the spaces between the chips are enlarged is maintained.

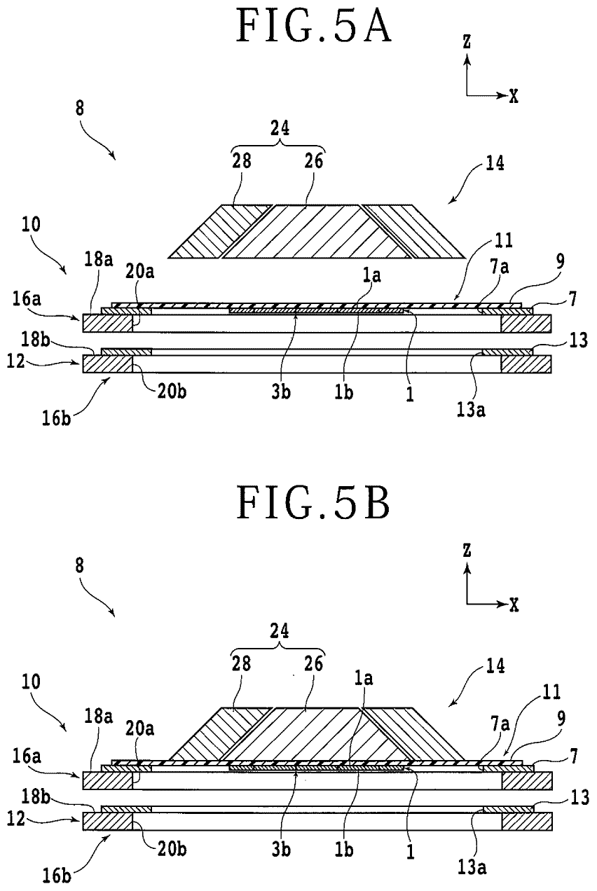

FIG. 5A and subsequent figures are cross-sectional views schematically illustrating an expansion apparatus 8. The expansion apparatus 8 that expands the expandable sheet 9 includes a first support unit 10 for supporting the first ring frame 7 of the workpiece unit 11, a second support unit 12 disposed to overlap the first support unit 10, and a sheet pressing expansion unit 14 capable of pressing and expanding the expandable sheet 9.

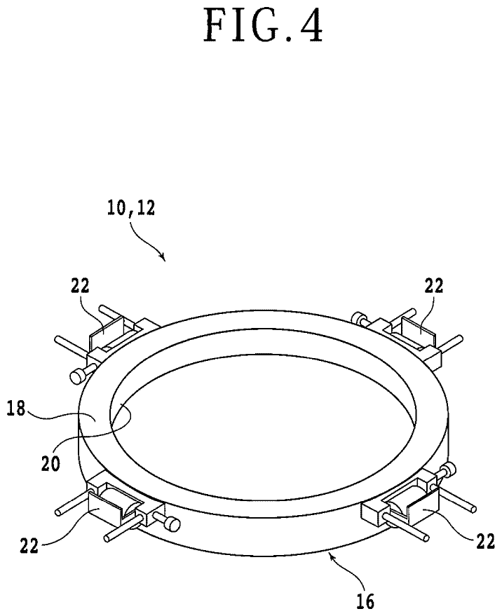

The first support unit 10 and the second support unit 12 included in the expansion apparatus 8 are configured in the same manner. FIG. 4 is a perspective view schematically illustrating a support unit included in the expansion apparatus 8. The first support unit 10 and the second support unit 12 each have an annular support portion (support table) 16 having a flat upper surface 18. An opening 20 defined in the support portion 16 of the first support unit 10 preferably has a diameter larger than the diameter of the opening 7a of the first ring frame 7. In addition, an opening 20 defined in the support portion 16 of the second support unit 12 preferably has a diameter larger than a diameter of an opening 13a of the second ring frame 13. However, the sizes of the openings 20 are not limited to the above examples.

The workpiece unit 11 is placed on the first support unit 10. At this time, the first ring frame 7 of the workpiece unit 11 is adjusted in position such that its opening 7a overlaps the opening 20 of the support portion 16 of the first support unit 10. In particular, positional adjustment is preferably performed such that the center of the opening 7a of the first ring frame 7 overlaps the center of the opening 20 of the support portion 16. Further, the second ring frame 13 is placed on the second support unit 12. At this time, the second ring frame 13 is adjusted in position such that its opening 13a overlaps the opening 20 of the support portion 16 of the second support unit 12. In particular, positional adjustment is preferably performed such that the center of the opening 13a of the second ring frame 13 overlaps the center of the opening 20 of the support portion 16.

In a case where the second support unit 12 is disposed below the first support unit 10, for example, it is possible that the first support unit 10 obstructs smooth carrying of the second ring frame 13 to/from the second support unit 12. This is because a space between the first support unit 10 and the second support unit 12 is narrow. To cope with this problem, the first support unit 10 and the second support unit 12 may be changeable in position relative to each other. For example, both or one of the first support unit 10 and the second support unit 12 may be movable upward and downward in a direction perpendicular to the opening 20 of the support portion 16. More specifically, in a case where the upper surface 18 of the support portion 16 lies in parallel to a horizontal direction, the support portion 16 may be moved upward and downward along a vertical direction. Alternatively, the support portion 16 may be moved along the horizontal direction.

The first support unit 10 may include a plurality of clamps 22 for fixing the first ring frame 7 of the workpiece unit 11 placed on the support portion 16. FIG. 4 illustrates four clamps 22 arranged at equal intervals on an outer peripheral surface of the support portion 16. It is to be noted that the clamps 22 are omitted from illustration in the figures except for FIG. 4. Similarly, the second support unit 12 includes a plurality of clamps 22 for fixing the second ring frame 13 placed on the support portion 16. In the expansion apparatus 8, the workpiece unit 11 including the expandable sheet 9 to be expanded is transported to the first support unit 10. At this time, the first ring frame 7 is fixed by the clamps 22. Further, the second ring frame 13 for fixing the expanded expandable sheet 9 is transported to the second support unit 12. At this time, the second ring frame 13 is fixed by the clamps 22. With such arrangements in the expansion apparatus 8, the expandable sheet 9 is pressed and expanded.

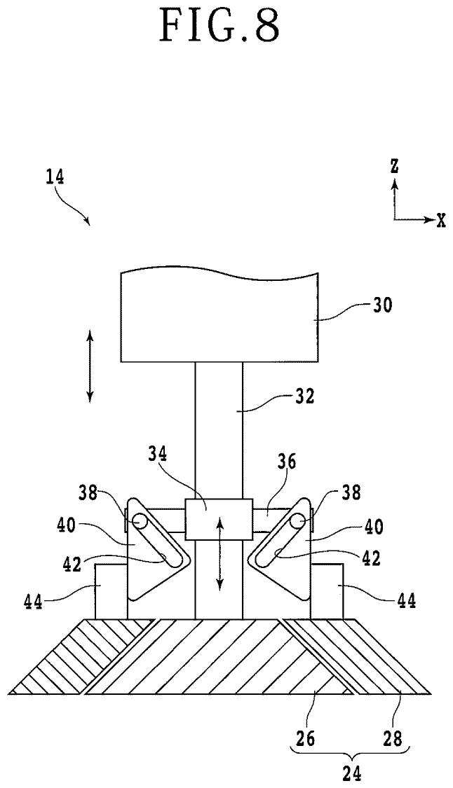

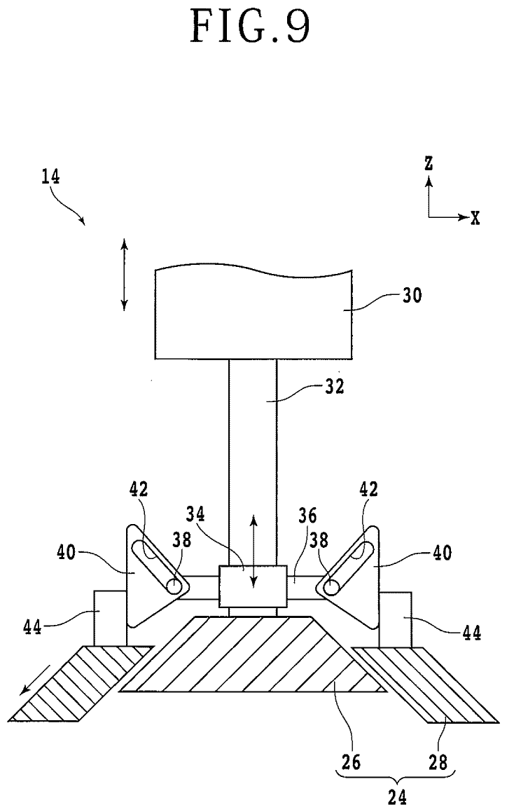

Described next is the sheet pressing expansion unit 14 that presses and expands the expandable sheet 9. FIG. 5A and subsequent figures are cross-sectional views schematically illustrating a pressing section 24 of the sheet pressing expansion unit 14. In addition, FIG. 8 and FIG. 9 are cross-sectional views schematically illustrating the sheet pressing expansion unit 14. The sheet pressing expansion unit 14 is capable of pressing the expandable sheet 9 of the workpiece unit 11 having the first ring frame 7 supported by the first support unit 10. In particular, the sheet pressing expansion unit 14 is capable of pressing a central area of the expandable sheet 9 surrounded by an area thereof attached to the first ring frame 7, in directions inclined radially outward with respect to a direction perpendicular to the opening 7a of the first ring frame 7. That is, the sheet pressing expansion unit 14 presses the expandable sheet 9 at a position inside the opening 7a of the first ring frame 7, thereby radially expanding the expandable sheet 9. Here, the central area of the expandable sheet 9 means an area exposed in the opening 7a of the first ring frame 7 and typically is an area including the center of the expandable sheet 9.

The sheet pressing expansion unit 14 includes a drive section (elevating mechanism) 30 and a movement support section (elevating shaft) 32 supporting respective constituent elements and being movable by the drive section 30. The drive section 30 is implemented, for example, by a moving mechanism including a motor, a ball screw, and the like or by an air cylinder. However, the drive section 30 is not limited to these examples. In a case where the drive section 30 is an air cylinder, an upper end of the movement support section 32 is connected to a piston included in the drive section 30. Further, the pressing section 24 is disposed at a lower portion of the movement support section 32. When the drive section (elevating mechanism) 30 is actuated, the pressing section 24 can be moved together with the movement support section (elevating shaft) 32. The drive section 30 can move the movement support section 32 (pressing section 24) along the direction perpendicular to the opening 7a of the first ring frame 7 supported by the first support unit 10.

In a case where the upper surface 18 or 18a of the first support unit 10 lies in parallel to a horizontal surface (XY plane), for example, the opening 7a of the first ring frame 7 placed on the first support unit 10 also lies in parallel to the horizontal surface (XY plane). In other words, when the first ring frame 7 is placed on the first support unit 10, the opening 7a penetrates the first ring frame 7 along the vertical direction (Z-axis direction) perpendicular to the horizontal surface. At this time, with the drive section 30 actuated, the movement support section 32 moves upward and downward along the vertical direction (Z-axis direction), and the pressing section 24 disposed to the movement support section 32 moves upward and downward accordingly.

It is to be noted that the upper surface 18 of the first support unit 10 is not necessarily required to be rigorously in parallel to the horizontal surface and that the opening 7a is not necessarily required to penetrate the first ring frame 7 rigorously in the vertical direction (Z-axis direction). That is, the drive section 30 does not need to move the movement support section 32 and the pressing section 24 upward and downward along a direction with no deviation from the vertical direction (Z-axis direction). In other words, when the drive section 30 moves the movement support section 32, it is not necessarily required to move the movement support section 32 and the pressing section 24 along a direction with no deviation from the direction (vertical direction) perpendicular to the opening 7a of the first ring frame 7 supported by the first support unit 10. Concerning the direction of moving the movement support section 32 and the pressing section 24, a certain degree of deviation from the direction (vertical direction) perpendicular to the opening 7a should be allowed as long as the expansion apparatus 8 according to the present embodiment can operate appropriately.

Described next is the pressing section 24 supported by the movement support section 32. As illustrated in FIG. 8 and FIG. 9, the pressing section 24 includes a fixed portion 26 directly fixed to a lower end of the movement support section 32 and a plurality of obliquely moving portions 28 arranged around the fixed portion 26. The obliquely moving portions 28 are not directly fixed to the movement support section 32.

The fixed portion 26 of the pressing section 24 is a hard member that is made of metal or the like and has a flat bottom surface, and is moved together with the movement support section 32. The bottom surface of the fixed portion 26 lies in parallel to the opening 7a of the first ring frame 7 supported by the first support unit 10. In the case where the movement support section 32 is moved along the vertical direction, the fixed portion 26 is also moved along the vertical direction, and the bottom surface of the fixed portion 26 lies in parallel to the horizontal surface. The fixed portion 26 has a function of pressing the expandable sheet 9 of the workpiece unit 11 supported by the first support unit 10. It is to be noted that the fixed portion 26 can be omitted from the pressing section 24.

The movement support section 32 further has an elevating body 34 slidably disposed thereon. For example, the elevating body 34 has a through hole (not illustrated) through which the movement support section 32 extends, and covers the movement support section 32 in a manner being in contact with an outer peripheral surface of the movement support section 32.

To the elevating body 34, there is connected a drive source (not illustrated) that provides driving force for sliding the elevating body 34 relative to the movement support section 32. Alternatively, the elevating body 34 incorporates a drive source (not illustrated) that provides driving force. For example, the sheet pressing expansion unit 14 may have a support body (not illustrated) for supporting the drive section 30, and in this case, the drive source for sliding the elevating body 34 relative to the movement support section 32 may be provided to the support body. Here, the drive source for sliding the elevating body 34 relative to the movement support section 32 is implemented, for example, by a moving mechanism of a ball screw type or by an air cylinder. However, the drive source is not limited to such examples.

To the elevating body 34, a plurality of support arms 36 for supporting the respective obliquely moving portions 28 of the pressing section 24 are fixed. Each support arm 36 extends from the elevating body 34 outward in a radial direction of the movement support section 32. A proximal end side of the support arm 36 is connected to the elevating body 34, and a cylindrical pin 38 extending in the horizontal direction is fixed to a distal end side of the support arm 36. There is further disposed a guide portion 40 having a guide hole 42 for slidably accommodating the pin 38. A plurality of such guide portions 40 are disposed around the movement support section 32. A support column 44 for supporting the relevant obliquely moving portion 28 described later is fixed to each guide portion 40. Each guide portion 40 is, for example, a flat plate-shaped member lying along a plane including the relevant radial direction of the movement support section 32 and the moving direction of the elevating body 34.

The guide hole 42 of the guide portion 40 is defined to be elongated in a direction inclined with respect to the moving direction of the elevating body 34 and penetrates from front to rear of the guide portion 40. The guide portion 40 is movable relative to the support arm 36 while the pin 38 is accommodated in the guide hole 42. In other words, the guide portion 40 is movable relative to the support arm 36 in a range within which the pin 38 can move along the guide hole 42. When the guide portion 40 moves relative to the support arm 36, the pin 38 accommodated in the guide hole 42 changes its position in the guide hole 42. Since the guide hole 42 is defined in the guide portion 40 to be elongated in the direction inclined with respect to the moving direction of the elevating body 34, the guide portion 40 moves relative to the support arm 36 along the direction inclined with respect to the moving direction of the elevating body 34.

In a case where the movement support section 32 extends along the vertical direction and the expandable sheet 9 to be expanded is disposed below the movement support section 32, for example, the guide portion 40 is oriented such that a lower end of the guide hole 42 is closer to the movement support section 32 than an upper end thereof is. In this case, when the elevating body 34 is moved relative to the movement support section 32, the support arm 36 moves together with the elevating body 34, and the pin 38 fixed to the support arm 36 slides inside the guide hole 42 of the guide portion 40. Receiving force from the pin 38, the guide portion 40 moves in a direction separating from or approaching the movement support section 32.

In the sheet pressing expansion unit 14, when the pressing section 24 is not pressing the expandable sheet 9, the elevating body 34 is at a high position with respect to the movement support section 32. In this state, the guide portion 40 is close to the movement support section 32.

Then, in order to expand the expandable sheet 9, first, the movement support section 32 moves to move the entire pressing section 24, and the expandable sheet 9 is pressed by the fixed portion 26 and the obliquely moving portions 28 of the pressing section 24. To further expand the expandable sheet 9, the elevating body 34 is moved to a lower position with respect to the movement support section 32. At this time, each guide portion 40 moves in a direction downward and separating from the movement support section 32.

The obliquely moving portions 28 fixed to the guide portions 40 through the support columns 44 move together with the guide portions 40. When the elevating body 34 is moved (downward) with respect to the movement support section 32, the obliquely moving portions 28 of the pressing section 24 move in respective directions downward and separating from the movement support section 32. That is, each obliquely moving portion 28 moves in a pressing direction that is a direction (oblique direction between the vertical direction and the horizontal direction, for example) inclined radially outward with respect to the direction (vertical direction, for example) perpendicular to the opening 7a of the first ring frame 7 supported by the first support unit 10. In this manner, the guide portions 40 guide the pressing section 24 (obliquely moving portions 28) in such a manner that the obliquely moving portions 28 move in the respective pressing directions.

The obliquely moving portions 28 press the expandable sheet 9 while passing through the opening 7a of the first ring frame 7 of the workpiece unit 11 supported by the first support unit 10, and distal ends (outermost ends) of the obliquely moving portions 28 advance to an area overlapping the first ring frame 7. In other words, the distal ends of the obliquely moving portions 28 advance to an area between the first ring frame 7 supported by the first support unit 10 and the second ring frame 13 supported by the second support unit 12. At this time, assuming a circle connecting the distal ends of the respective obliquely moving portions 28 of the pressing section 24, this circle has a diameter larger than the diameter of the opening 7a of the first ring frame 7.

While the distal ends of the obliquely moving portions 28 of the pressing section 24 are advancing to the area between the first ring frame 7 and the second ring frame 13, the expandable sheet 9 is kept being expanded. The obliquely moving portions 28 of the pressing section 24 move until the expandable sheet 9 eventually makes contact with the second ring frame 13.

In the process so far, along with the expansion of the expandable sheet 9, spaces 3b between chips 15 formed as a result of the division of the workpiece 1 from the division initiating points (modified layers 3a) are enlarged. Alternatively, spaces 3b between chips 15 formed as the result of the division of the workpiece 1 by the division grooves are enlarged. In any case, distances between the respective chips 15 formed as the result of the division of the workpiece 1 with use of the division initiating points (modified layers 3a) or the division grooves as boundaries are increased.

The obliquely moving portions 28 have a shape determined such that the obliquely moving portions 28 do not make contact with the first ring frame 7 and the like at this time. For example, the distal end portion of each obliquely moving portion 28 has a thickness smaller than the distance between the first ring frame 7 and the second ring frame 13. Alternatively, the distal end portion of each obliquely moving portion 28 has a thickness smaller than the distance between the upper surface 18a of the support portion 16a of the first support unit 10 and the upper surface 18b of the support portion 16b of the second support unit 12. Here, the thickness of the distal end portion of each obliquely moving portion 28 means the thickness in the direction (vertical direction, for example) perpendicular to the opening 7a of the first ring frame 7.

The following is a summary of the sheet pressing expansion unit 14 described above. The sheet pressing expansion unit 14 includes the movement support section 32 and the drive section 30 that moves the movement support section 32 along the direction perpendicular to the opening 7a of the first ring frame 7 supported by the first support unit 10. The sheet pressing expansion unit 14 further includes the pressing section 24 (obliquely moving portions 28) that is supported by the movement support section 32 through the guide portions 40 and presses the expandable sheet 9. The guide portions 40 guide the pressing section 24 (obliquely moving portions 28) in such a manner that the obliquely moving portions 28 move in the respective pressing directions inclined radially outward with respect to the direction perpendicular to the opening 7a of the first ring frame 7. By expanding the expandable sheet 9, the sheet pressing expansion unit 14 increases the distances between the respective chips 15 formed as the result of the division of the workpiece 1 with use of the division initiating points (modified layers 3a) or the division grooves as boundaries. In addition, the sheet pressing expansion unit 14 fixes the expanded expandable sheet 9 to the second ring frame 13 disposed on the second support unit 12.

In this manner, in the expansion apparatus 8 according to the present embodiment, the obliquely moving portions 28 of the pressing section 24 can advance in the respective directions inclined radially outward with respect to the direction perpendicular to the opening 7a of the first ring frame 7. Therefore, even in the case where the first ring frame 7 and the second ring frame 13 have similar planar shape, the distal ends of the obliquely moving portions 28 can advance to the area between the first ring frame 7 and the second ring frame 13 and press the expandable sheet 9 against the second ring frame 13. Further, in the expansion apparatus 8 according to the present embodiment, the expandable sheet 9 is attached to the second ring frame 13 in a relatively large flat area around the workpiece 1 (chips 15 formed as the result of the division of the workpiece 1). The expandable sheet 9 is thus attached to the second ring frame 13 by sufficient fixing force.

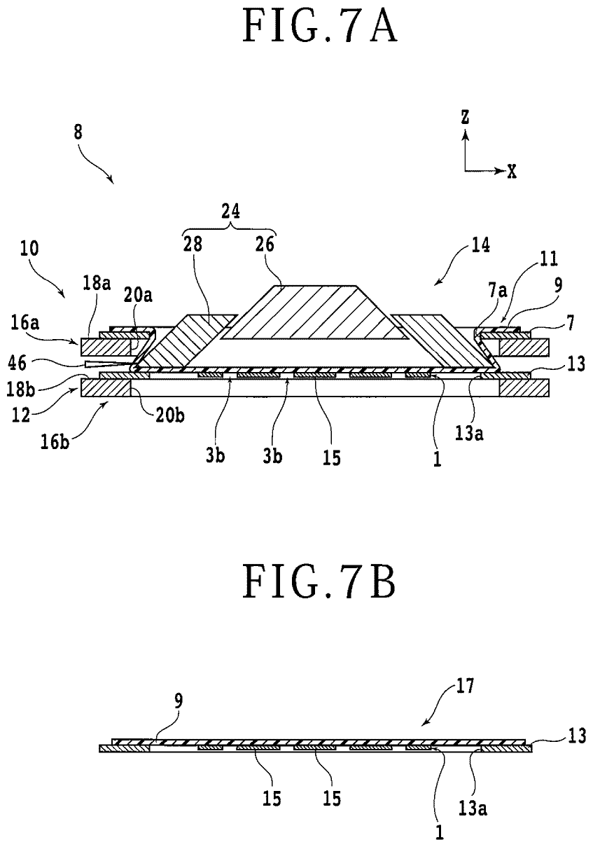

Moreover, the expansion apparatus 8 according to the present embodiment may further include a cutting unit (cutter) for cutting the expandable sheet 9 fixed to the second ring frame 13, along the opening 13a of the second ring frame 13. FIG. 7A is a cross-sectional view schematically illustrating a cutter 46 for cutting the expandable sheet 9.

The cutter 46 enters the area between the first support unit 10 and the second support unit 12 and cuts into the expandable sheet 9 from outside toward a side surface of the opposed one of the obliquely moving portions 28 of the pressing section 24. Then, the cutter 46 in the state of cutting into the expandable sheet 9 moves to make one revolution or more along the opening 13a of the second ring frame 13, thereby separating the central area of the expandable sheet 9 from the first ring frame 7. Thus, a frame unit including the second ring frame 13, the expandable sheet 9, and the workpiece 1 (chips 15) is formed. FIG. 7B is a cross-sectional view schematically illustrating a frame unit 17. Since the spaces between the respective chips 15 are kept wide in the frame unit 17, it is easy to pick up the chips 15 from the expandable sheet 9.

It is to be noted that the cutter 46 is not necessarily required to cut into the expandable sheet 9 toward the side surface of the opposed one of the obliquely moving portions 28 of the pressing section 24 and may cut into the expandable sheet 9 toward a front surface of the second ring frame 13. However, if the cutter 46 cuts into the expandable sheet 9 toward the second ring frame 13, a flaw is generated by the cutter 46 on the front surface of the second ring frame 13. In contrast, in the case where the cutter 46 cuts into the expandable sheet 9 toward the side surface of the opposed one of the obliquely moving portions 28, no flaw is generated on the front surface of the second ring frame 13, so that the second ring frame 13 can be reused for a long period of time.

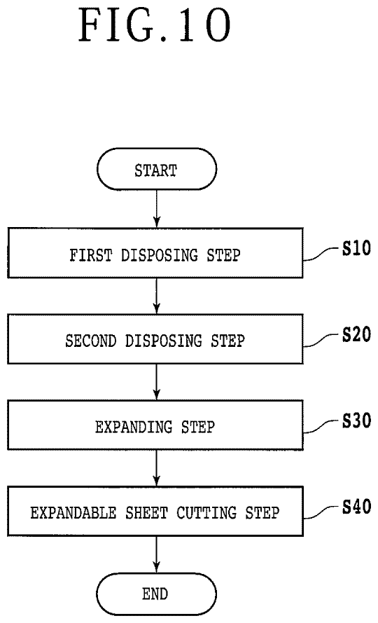

Next, as one usage mode of the expansion apparatus 8 according to the present embodiment, the expansion method for expanding the expandable sheet 9 by use of the expansion apparatus 8 is described. FIG. 10 is a flowchart illustrating a flow of steps in the expansion method for expanding the expandable sheet 9. The respective steps are described in detail below.

First, a first disposing step S10 of disposing the first ring frame 7 of the workpiece unit 11 on the first support unit 10 and a second disposing step S20 of disposing the second ring frame 13 on the second support unit 12 overlapping the first support unit 10 are performed. FIG. 5A is a cross-sectional view schematically illustrating the workpiece unit 11 disposed on the first support unit 10 and the second ring frame 13 disposed on the second support unit 12. It is to be noted that the first disposing step S10 and the second disposing step S20 may be performed simultaneously, or one of the first disposing step S10 and the second disposing step S20 may be performed earlier than the other.

In the first disposing step S10, the workpiece unit 11 including the workpiece 1 having the division initiating points (modified layers 3a) or the division grooves formed therein, the first ring frame 7, and the expandable sheet 9 is transported to the first support unit 10. Then, the first ring frame 7 is placed on the upper surface 18a of the support portion 16a of the first support unit 10. At this time, preferably, the first ring frame 7 is adjusted in position such that the center of the opening 7a of the first ring frame 7 overlaps the center of the opening 20a of the support portion 16a of the first support unit 10. Thereafter, the first ring frame 7 is fixed to the first support unit 10 by the clamps 22 of the first support unit 10.

Further, in the second disposing step S20, the second ring frame 13 is transported to the second support unit 12 and placed on the upper surface 18b of the support portion 16b. At this time, preferably, the second ring frame 13 is adjusted in position such that the center of the opening 13a of the second ring frame 13 overlaps the center of the opening 20b of the support portion 16b of the second support unit 12. Thereafter, the second ring frame 13 is fixed to the second support unit 12 by the clamps 22 of the second support unit 12.

It is to be noted that ring frames of the same shape can be used as the first ring frame 7 and the second ring frame 13. That is, the planar shape of the first ring frame 7 may coincide with the planar shape of the second ring frame 13. In the case where ring frames of the same shape are used, it is possible to utilize a mechanism or container used to transport the first ring frame 7 for transporting the second ring frame 13, so that there is no need to prepare two different mechanisms or containers specialized for transportation of the respective ring frames. That is, the first ring frame 7, the second ring frame 13, and the like can efficiently be transported. Here, in the case where ring frames of the same shape are used as the first ring frame 7 and the second ring frame 13, it is preferable that the first ring frame 7 and the second ring frame 13 completely overlap each other when the first disposing step S10 and the second disposing step S20 have been performed. In this case, the opening 7a of the first ring frame 7 and the opening 13a of the second ring frame 13 completely overlap each other.

After the first disposing step S10 and the second disposing step S20, an expanding step S30 of pressing the expandable sheet 9 to radially expand the expandable sheet 9 is performed. The pressing of the expandable sheet 9 in the expanding step S30 is performed by the sheet pressing expansion unit 14 of the expansion apparatus 8. In the expanding step S30, the pressing section 24 of the sheet pressing expansion unit 14 is moved downward to make contact with the expandable sheet 9, and is further moved downward to press the expandable sheet 9. Thereafter, the pressing section 24 is moved radially (outward in the radial directions) while being further moved downward, thereby fixing the expandable sheet 9 to the second ring frame 13. Respective stages of the expanding step S30 are described below.

In the expanding step S30, first, the pressing section 24 is moved downward such that the pressing section 24 (the fixed portion 26 and the obliquely moving portions 28) makes contact with the expandable sheet 9. FIG. 5B is a cross-sectional view schematically illustrating how the sheet pressing expansion unit 14 is moved downward. It is to be noted that, when the pressing section 24 of the sheet pressing expansion unit 14 is to be moved downward, the movement support section 32 (refer to FIG. 8 and FIG. 9) is moved downward. At this time, the elevating body 34 is not moved relative to the movement support section 32.

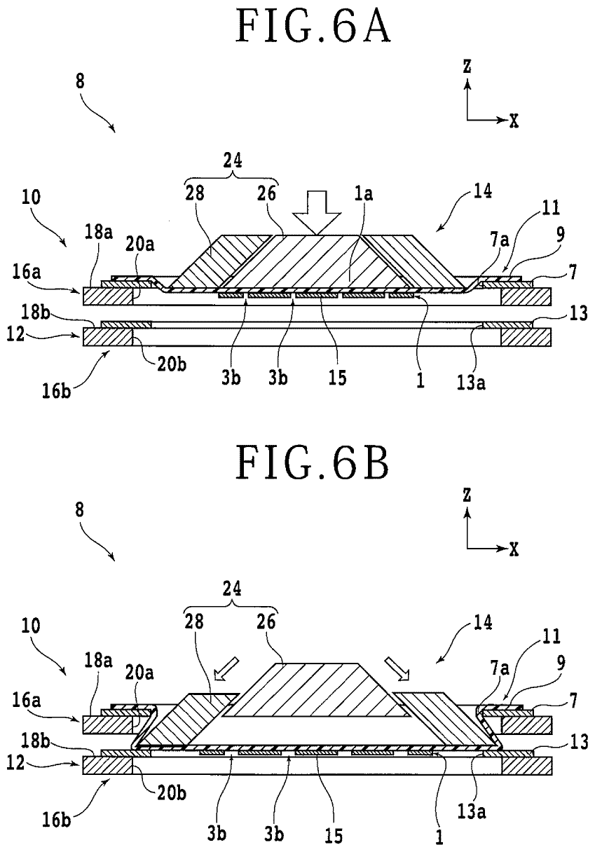

When the pressing section 24 is further moved downward after it makes contact with the expandable sheet 9, the expandable sheet 9 is pressed by the pressing section 24. FIG. 6A is a cross-sectional view schematically illustrating how the expandable sheet 9 is pressed by the pressing section 24. When the pressing of the central area of the expandable sheet 9 inside the opening 7a of the first ring frame 7 by the pressing section 24 is started, the expandable sheet 9 starts to be expanded radially outward. When the expandable sheet 9 is expanded, radially outward force is applied to the workpiece 1 fixed to the expandable sheet 9.

For example, in the case where the division initiating points (modified layers 3a) have been formed in the workpiece 1 at the time of start of the expanding step S30, the radially outward force applied to the workpiece 1 divides the workpiece 1 along the division initiating points (modified layers 3a). As a result, the individual chips 15 are formed, and the spaces 3b are generated between adjacent ones of the chips 15. Alternatively, for example, in the case where the division grooves have been formed in the workpiece 1 and the chips 15 have been formed at the time of start of the expanding step S30, the radially outward force applied to the workpiece 1 enlarges the spaces 3b between the respective chips 15. In any case, in the expanding step S30, the distances between the respective chips 15 formed as the result of the division of the workpiece 1 with use of the division initiating points (modified layers 3a) or the division grooves as boundaries are increased.

In the expanding step S30, next, the central area of the expandable sheet 9 surrounded by the area thereof fixed to the first ring frame 7 is pressed in the directions inclined radially outward with respect to the direction perpendicular to the opening 7a of the first ring frame 7. Here, “radially outward” means, for example, a direction from the center toward the outer periphery of the workpiece 1. Then, the expanded expandable sheet 9 is fixed to the second ring frame 13 disposed on the second support unit 12. FIG. 6B is a cross-sectional view schematically illustrating how the expandable sheet 9 thus pressed and expanded is fixed to the second ring frame 13.

When the expandable sheet 9 is to be pressed in the directions (directions between the vertical direction and the horizontal direction, for example) inclined radially outward with respect to the direction perpendicular to the opening 7a of the first ring frame 7, the elevating body 34 is moved (downward) with respect to the movement support section 32 as illustrated in FIG. 9. Then, due to the function of the guide portions 40, the obliquely moving portions 28 of the pressing section 24 advance in these inclined directions (pressing directions).

For example, in the case where the planar shapes of the first ring frame 7 and the second ring frame 13 coincide with each other, the distal ends (outermost ends) of the pressing section 24 enter the area sandwiched between the first ring frame 7 and the second ring frame 13. As a result, part of the portion of the expandable sheet 9 yet to be expanded which portion is exposed between the first ring frame 7 and the workpiece 1 enters the area sandwiched between the first ring frame 7 and the second ring frame 13.

Whether the planar shapes of the first ring frame 7 and the second ring frame 13 coincide with each other or not, the pressing section 24 (obliquely moving portions 28) presses the expandable sheet 9 against the second ring frame 13. In the case where the expandable sheet 9 is a tape including an adhesive layer, the expandable sheet 9 is attached to the second ring frame 13 by the adhesive layer at this time. This maintains the expanded state of the expandable sheet 9 inside the opening 13a of the second ring frame 13, so that the spaces 3b between the chips 15 are kept wide.

In the case where the expandable sheet 9 is a sheet having no adhesive layer, the expansion apparatus 8 preferably includes a heating unit that heats the expandable sheet 9. Further, it is preferable that, when the expandable sheet 9 is pressed against the second ring frame 13 by the pressing section 24 (obliquely moving portions 28), the heating unit heat the expandable sheet 9 to reach a predetermined temperature. In this case, the expandable sheet 9 is fixed to the second ring frame 13 by thermocompression bonding.

It is to be noted that, in the case where the expansion apparatus 8 includes the heating unit contributable to thermocompression bonding of the expandable sheet 9, for example, the heating unit may be incorporated in the support portion 16b of the second support unit 12 or may be incorporated in the obliquely moving portions 28 of the pressing section 24. In such cases, a heater or the like including heating wires and the like can be used as the heating unit. In the case where the support portion 16b incorporates the heating unit, the heating unit heats, through the second ring frame 13, the expandable sheet 9 in contact with the second ring frame 13. Moreover, the heating unit is not necessarily required to be incorporated in the support portion 16b of the second support unit 12 or the like, and there may be used a heat gun for feeding a predetermined area of the expandable sheet 9 with hot air or an infrared lamp for irradiating a predetermined area of the expandable sheet 9 with infrared light.

In the expansion method performed by the expansion apparatus 8 for expanding the expandable sheet 9, an expandable sheet cutting step S40 may be performed after the expanding step S30. In the expandable sheet cutting step S40, the expandable sheet 9 fixed to the second ring frame 13 is cut along the opening 13a of the second ring frame 13. The cutting unit (cutter 46) of the expansion apparatus 8 may be used to cut the expandable sheet 9 in the expandable sheet cutting step S40. FIG. 7A is a cross-sectional view schematically illustrating how the expandable sheet 9 is cut by the cutting unit (cutter 46).

In the expandable sheet cutting step S40, first, the cutter 46 is inserted from outside into the space between the support portion 16a of the first support unit 10 and the support portion 16b of the second support unit 12 and is caused to cut into the expandable sheet 9. In this state, the cutter 46 is moved along the opening 13a of the second ring frame 13. For example, the cutter 46 is caused to make one revolution around the opening 13a. When the cutter 46 cuts the expandable sheet 9 along the opening 13a, the central area of the expandable sheet 9 is separated from the first ring frame 7. The frame unit 17 (refer to FIG. 7B) including the separated workpiece 1 (chips 15), the expandable sheet 9, and the second ring frame 13 is thus formed. Thereafter, the frame unit 17 and the first ring frame 7 are carried out from the expansion apparatus 8.

FIG. 7B is a cross-sectional view schematically illustrating the frame unit 17. In the frame unit 17, the chips 15 are fixed to the expandable sheet 9 in the state in which the expandable sheet 9 has been expanded and the distances between the chips 15 have been increased as illustrated in FIG. 7B, and hence, it is easy to pick up the individual chips 15.

As described above, in the case where the expansion method for expanding the expandable sheet 9 by the expansion apparatus 8 is performed, the expandable sheet 9 is not merely pressed in the direction perpendicular to the opening 7a of the first ring frame 7 but pressed in the directions inclined radially outward and expanded. Therefore, a large flat area can be formed in the expandable sheet 9 around the workpiece 1 (divided chips 15). In this case, since the expandable sheet 9 is attached to the second ring frame 13 in this relatively large flat area, the expandable sheet 9 is attached to the second ring frame 13 by sufficient fixing force. In addition, in this case, heat shrinking for causing shrinkage of the expanded expandable sheet 9 does not need to be performed. In particular, in the case where the first ring frame 7 and the second ring frame 13 have the same planar shape, the frame unit 17 can be transported using a cassette that is used to accommodate and transport the workpiece unit 11, and hence, the chips 15 can efficiently be transported in the state of being included in the frame unit 17. Accordingly, the time and cost required for the process can be reduced, so that chips can be manufactured with high efficiency.

It is to be noted that, in the case described in the above embodiment, the first support unit 10 is positioned above the second support unit 12, the first ring frame 7 of the workpiece unit 11 is disposed above the second ring frame 13, and the expandable sheet 9 is pressed from above. However, aspects of the present invention are not limited to this case. That is, in the expansion apparatus 8 and the expansion method for expanding the expandable sheet 9 according to one aspect of the present invention, the first support unit 10 may be disposed below the second support unit 12, and the first ring frame 7 may be disposed below the second ring frame 13. Further, the expandable sheet 9 may be pressed from below.

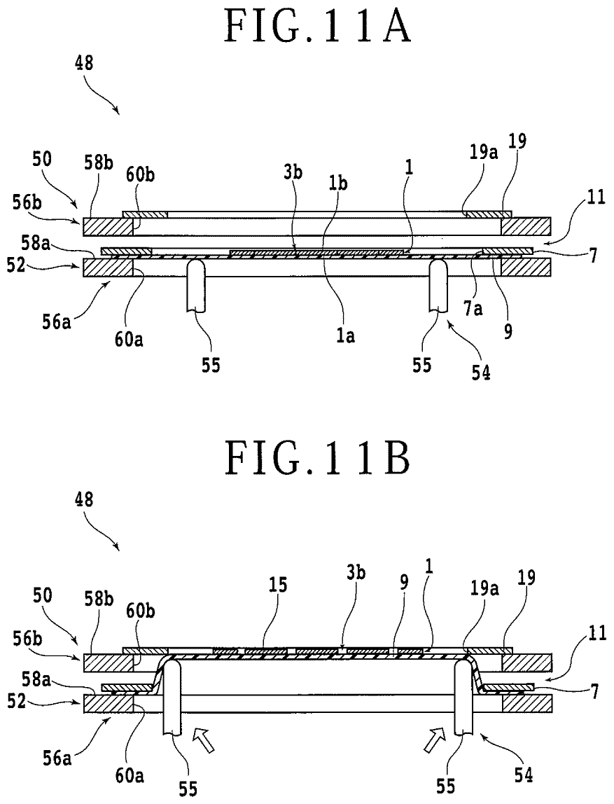

FIG. 11A is a cross-sectional view schematically illustrating an expansion apparatus 48 according to a modification example. Described next is the expansion apparatus 48 according to the modification example. See the above description of the expansion apparatus 8 for elements that are not particularly described here concerning the expansion apparatus 48 according to the modification example.

The expansion apparatus 48 for expanding the expandable sheet 9 includes a first support unit 52 that supports the first ring frame 7 of the workpiece unit 11, a second support unit 50 overlapping the first support unit 52, and a sheet pressing expansion unit 54 capable of pressing and expanding the expandable sheet 9. In the expansion apparatus 48 according to the modification example, the second support unit 50 is disposed above the first support unit 52. The first support unit 52 and the second support unit 50 have annular support portions (support tables) 56a and 56b having flat upper surfaces 58a and 58b, respectively. The first support unit 52 and the second support unit 50 may have the clamps 22 (refer to FIG. 4) for fixing the ring frame placed thereon, as with the first support unit 10 and the second support unit 12 of the expansion apparatus 8 described above.

The sheet pressing expansion unit 54 of the expansion apparatus 48 presses the expandable sheet 9 from below to expand the expandable sheet 9. The sheet pressing expansion unit 54 of the expansion apparatus 48 according to the modification example includes pressing sections 55 that press the expandable sheet 9 from below. Here, unlike the expansion apparatus 8 described above, the expansion apparatus 48 does not include two kinds of component, i.e., the fixed portion 26 and the obliquely moving portions 28, as the pressing sections 55 of the sheet pressing expansion unit 54.

The pressing sections 55 of the sheet pressing expansion unit 54 press the expandable sheet 9 while passing through the opening 7a of the first ring frame 7 of the workpiece unit 11 supported by the first support unit 52. At this time, the pressing sections 55 advance in respective directions (directions between the vertical upward direction and the horizontal direction, or pressing directions) inclined radially outward with respect to the direction (vertical upward direction) perpendicular to the opening 7a of the first ring frame 7.

Then, the pressing sections 55 bring the expandable sheet 9 into contact with a second ring frame 19 and press the expandable sheet 9 against the second ring frame 19, thereby fixing the expandable sheet 9 to the second ring frame 19. FIG. 11B is a cross-sectional view schematically illustrating how the expandable sheet 9 is expanded in the expansion apparatus 48 according to the modification example.

It is to be noted that, as illustrated in FIG. 11A and FIG. 11B, the second ring frame 19 to which the expanded expandable sheet 9 is fixed does not need to be a ring frame of a type same as that of the first ring frame 7. For example, the second ring frame 19 may be smaller in size than the first ring frame 7, and an opening 19a of the second ring frame 19 may be smaller in diameter than the opening 7a of the first ring frame 7.

However, in this case as well, the opening 19a of the second ring frame 19 needs to have a size large enough to accommodate the workpiece 1 (plurality of chips 15) fixed to the expanded expandable sheet 9. In this case, distal end portions (upper end portions) of the pressing sections 55 that press the expandable sheet 9 do not need to advance to an area between the first ring frame 7 and the second ring frame 19. Even if the distal end portions of the pressing sections 55 do not enter this area, the pressing sections 55 can press the expandable sheet 9 against the second ring frame 19.

After expanding and pressing the expandable sheet 9 by using the sheet pressing expansion unit 54 to fix the expandable sheet 9 to the second ring frame 19, the expansion apparatus 48 may cut the expandable sheet 9 along the opening 19a of the second ring frame 19. With the expandable sheet 9 cut, a frame unit including the expanded expandable sheet 9, the second ring frame 19, and the workpiece 1 (chips 15) is formed.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. An expansion method for expanding an expandable sheet of a workpiece unit including a plate-shaped workpiece in which division initiating points or division grooves are formed, a first ring frame having an opening and disposed to surround the workpiece, and the expandable sheet attached to the workpiece and the first ring frame, the expansion method comprising:
disposing the first ring frame of the workpiece unit on a first support unit;
disposing a second ring frame having an opening, on a second support unit overlapping the first support unit; and
radially expanding, after disposing the first ring frame and the second ring frame, the expandable sheet by pressing the expandable sheet at a position inside the opening of the first ring frame,
wherein, in the expanding, a central area of the expandable sheet which central area is surrounded by an area attached to the first ring frame is pressed in directions inclined radially outward with respect to a direction perpendicular to the opening of the first ring frame,
in the expanding, distances between respective chips formed as a result of division of the workpiece with use of the division initiating points or the division grooves as boundaries are increased, and
in the expanding, the expanded expandable sheet is fixed to the second ring frame disposed on the second support unit.

2. The expansion method according to claim 1,
wherein a planar shape of the first ring frame coincides with a planar shape of the second ring frame,
when the first ring frame and the second ring frame are disposed, the opening of the first ring frame overlaps the opening of the second ring frame, and
part of a portion of the expandable sheet yet to be expanded which portion is exposed between the first ring frame and the workpiece enters an area sandwiched between the first ring frame and the second ring frame when the expanding is performed.

3. The expansion method according to claim 1, further comprising:
cutting, after the expanding, the expandable sheet fixed to the second ring frame along the opening of the second ring frame.

4. An expansion apparatus for expanding an expandable sheet of a workpiece unit including a plate-shaped workpiece in which division initiating points or division grooves are formed, a first ring frame having an opening and disposed to surround the workpiece, and the expandable sheet attached to the workpiece and the first ring frame, the expansion apparatus comprising:
a first support unit that supports the first ring frame of the workpiece unit;
a second support unit that supports a second ring frame having an opening, the second support unit overlapping the first support unit; and
a sheet pressing expansion unit capable of pressing a central area of the expandable sheet of the workpiece unit having the first ring frame supported by the first support unit which central area is surrounded by an area attached to the first ring frame, in pressing directions inclined radially outward with respect to a direction perpendicular to the opening of the first ring frame,
wherein the sheet pressing expansion unit is capable of expanding the expandable sheet to increase distances between respective chips formed as a result of division of the workpiece with use of the division initiating points or the division grooves as boundaries, and also capable of fixing the expanded expandable sheet to the second ring frame disposed on the second support unit.

5. The expansion apparatus according to claim 4,
wherein the sheet pressing expansion unit includes
a movement support section,
a drive section that moves the movement support section along the direction perpendicular to the opening of the first ring frame supported by the first support unit, and
pressing sections that are supported by the movement support section through guide portions and press the expandable sheet, and
the guide portions guide the respective pressing sections in such a manner that the pressing sections move in the respective pressing directions.

6. The expansion apparatus according to claim 4,
wherein a planar shape of the first ring frame supported by the first support unit coincides with a planar shape of the second ring frame supported by the second support unit.

7. The expansion apparatus according to claim 4, further comprising:
a cutter for cutting the expandable sheet fixed to the second ring frame along the opening of the second ring frame.
